(19) United States
(12) Patent Application Publication
(10) Pub. No.: US 2023/0178958 A1
(43) Pub. Date: Jun. 8, 2023

(54) RADIATION-EMITTING SEMICONDUCTOR LASER AND METHOD FOR OPERATING A RADIATION-EMITTING SEMICONDUCTOR LASER

(71) Applicant: ams-OSRAM International GmbH, Regensburg (DE)

(72) Inventors: John BRÜCKNER, Regensburg (DE); Sven GERHARD, Alteglofsheim (DE)

(73) Assignee: ams-OSRAM International GmbH, Regensburg (DE)

(21) Appl. No.: 17/919,601

(22) PCT Filed: Apr. 21, 2021
(86) PCT No.: PCT/EP2021/060364

§ 371 Date: Oct. 18, 2022

(30) Foreign Application Priority Data
Apr. 22, 2020 (DE) 10 2020 205 118.6

(51) Int. Cl. H01S 5/024; H01S 5/323; H01S 5/026; H01S 5/00

(52) U.S. Cl. CPC H01S 5/024; H01S 5/323; H01S 5/0261; H01S 5/0014; H01S 5/22

(57) ABSTRACT

The invention relates to a radiation-emitting semiconductor laser comprising—a semiconductor body comprising an active region which is designed to generate electromagnetic radiation, —a resonator which has a first end region and a second end region, and —a first sensor layer which is designed to measure the temperature of the semiconductor body, wherein the active region is located in the resonator in such a way that the electromagnetic radiation generated in the active region during operation is electromagnetic laser radiation, and —the first sensor layer is located in the first active end region of the resonator. The invention also relates to a method for operating a radiation-emitting semiconductor laser.

### CROSS-REFERENCE TO RELATED APPLICATIONS

This patent application is a national stage entry from International Application No. PCT/EP2021/060364, filed on Apr. 21, 2021, published as International Publication No. WO 2021/214131 A1 on Oct. 28, 2021, and claims priority to German Patent Application No. 10 2020 205 118.6, filed Apr. 22, 2020, the entire contents of all of which are incorporated by reference herein.

### FIELD OF THE INVENTION

A radiation-emitting semiconductor laser is specified. Furthermore, a method for operating a radiation-emitting semiconductor laser is specified.

### BACKGROUND OF THE INVENTION

One object to be achieved is to specify a radiation-emitting semiconductor laser that is operable particularly efficiently. Moreover, the intention is to specify a method for operating such a radiation-emitting semiconductor laser.

These objects are achieved by means of a radiation-emitting semiconductor laser having the features of patent claim 1 and by means of a method having the steps of patent claim 14.

The respective dependent claims relate to advantageous embodiments of the radiation-emitting semiconductor laser and of the method for operating the radiation-emitting semiconductor laser.

### SUMMARY OF THE INVENTION

In accordance with at least one embodiment, the radiation-emitting semiconductor laser comprises a semiconductor body, comprising an active region configured to generate electromagnetic radiation. The active region preferably has a main extension plane. A vertical direction preferably extends perpendicular to the main extension plane and a lateral direction preferably extends parallel to the main extension plane.

Preferably, the semiconductor body comprises a first semiconductor layer sequence of a first conductivity type and a second semiconductor layer sequence of a second conductivity type, which is different than the first conductivity type. By way of example, the first semiconductor layer sequence is configured such that it is p-doped and thus p-conducting. Furthermore, the second semiconductor layer sequence is configured for example such that it is n-doped and thus n-conducting. Therefore, the first conductivity type is for example a p-conducting type and the second conductivity type is for example an n-conducting type.

The semiconductor body is preferably grown epitaxially. That is to say that the first semiconductor layer sequence and the second semiconductor layer sequence are preferably grown epitaxially one above the other in a vertical direction.

The active region is preferably arranged between the first semiconductor layer sequence and the second semiconductor layer sequence. The active region preferably directly adjoins the first semiconductor layer sequence and the second semiconductor layer sequence. The active region preferably has a pn junction for generating the electromagnetic radiation, such as, for example, a double heterostructure, a single quantum well structure or a multiquantum well structure.

The semiconductor body is preferably formed from a III/V compound semiconductor or comprises a III/V compound semiconductor. The III/V compound semiconductor can be an arsenide compound semiconductor, a nitride compound semiconductor or a phosphide compound semiconductor.

By way of example, the semiconductor body, in particular the active region, is based on an arsenide compound semiconductor or consists of one or more arsenide compound semiconductors. Arsenide compound semiconductors contain arsenic, such as the materials from the system InₓAl_{y}Ga_{1-x-y}As where 0≤x≤1, 0≤y≤1 and x+y≤1. Active regions of this type are generally configured to generate red to infrared light.

Alternatively, the semiconductor body, in particular the active region, is based on a nitride compound semiconductor or consists of one or more nitride compound semiconductors. Nitride compound semiconductors contain nitrogen, such as the materials from the system InₓAl_{y}Ga_{1-x-y}N where 0≤x≤1, 0≤y≤1 and x+y≤1. Active regions of this type are generally configured to generate ultraviolet to blue light, in particular ultraviolet to green light.

Furthermore, it is possible for the semiconductor body, in particular the active region, to be based on a phosphide compound semiconductor or to consist of one or more phosphide compound semiconductors. Phosphide compound semiconductors contain phosphorus, such as the materials from the system InₓAl_{y}Ga_{1-x-y}P where 0≤x≤1, 0≤y≤1 and x+y≤1. Active regions of this type are generally configured to generate green to red light, in particular green to infrared light.

In accordance with at least one embodiment, the radiation-emitting semiconductor laser comprises a resonator comprising a first end region and a second end region. The first end region of the resonator preferably has a first main surface of the semiconductor body. The second end region of the resonator preferably has a second main surface of the semiconductor body.

The first main surface and the second main surface are preferably situated opposite one another. Furthermore, the first main surface and the second main surface are preferably formed parallel to one another. The active region is preferably arranged between the first end region and the second end region, in particular between the first main surface and the second main surface.

Preferably, the first main surface and the second main surface are arranged perpendicular to the main extension plane. The active region preferably extends from the first main surface to the second main surface. That is to say that the active region is bounded by the first main surface and the second main surface in a lateral direction.

Alternatively, the first main surface and the second main surface are arranged parallel to the main extension plane. The active region is arranged for example between the first main surface and the second main surface in a vertical direction. In particular, in this case, the active region is not bounded by the first main surface and the second main surface in a lateral direction.

In accordance with at least one embodiment, the radiation-emitting semiconductor laser comprises a first sensor layer configured for measuring a temperature of the semiconductor body. In other words, the first sensor layer is preferably a temperature sensor. The first sensor layer is preferably formed with a material in which a resistance changes depending on a temperature. A first sensor layer of this type is for example an MTC thermistor, the resistance of which decreases as the temperature increases, or a PTC thermistor, the resistance of which increases as the temperature increases.

Alternatively, the first sensor layer is a thermocouple, for example. In this case, the sensor layer comprises at least two metals. Between the two metals, a measurable thermal voltage preferably changes depending on the temperature of the semiconductor body.

Preferably, the first sensor layer is shaped as a strip. Preferably, the first sensor layer has a width of at least 0.1 micrometer and at most 30 micrometers, in particular of at least 1 micrometer and at most 5 micrometers. Furthermore, the first sensor layer has a length of at least 1 micrometer and at most 150 micrometers, in particular of at least 50 micrometers and at most 100 micrometers. Moreover, the first sensor layer preferably has a thickness in a vertical direction of at least 20 nanometers and at most 2000 nanometers, in particular of at least 500 nanometers and at most 1000 nanometers.

In accordance with at least one embodiment of the radiation-emitting semiconductor laser, the active region is arranged in the resonator in such a way that the electromagnetic radiation generated in the active region during operation is electromagnetic laser radiation.

Preferably, electrical energy is fed to the active region. The feeding of electrical energy produces a population inversion of charge carriers in the active region. Furthermore, the electromagnetic radiation is generated by the feeding of electrical energy in the active region.

The electromagnetic radiation generated in the active region is reflected multiply within the resonator. The reflected electromagnetic radiation furthermore generates a stimulated emission of electromagnetic laser radiation in the active region as a result of the population inversion. The electromagnetic laser radiation, too, is reflected multiply within the resonator and can further generate electromagnetic laser radiation by way of stimulated emission.

Furthermore, a length of the resonator is preferably an integer multiple of a wavelength of the electromagnetic laser radiation to be generated. Electromagnetic radiation having a different wavelength, for example, is thus preferably suppressed by destructive interference.

In contrast to electromagnetic radiation generated by spontaneous emission, the electromagnetic laser radiation generated by stimulated emission generally has a very high coherence length, a very narrow emission spectrum and/or a high degree of polarization.

If the first main surface and the second main surface are arranged perpendicular to the main extension plane, the radiation-emitting semiconductor laser is an edge emitting semiconductor laser. Preferably, the first main surface perpendicular to the main extension plane is a radiation exit surface of the electromagnetic laser radiation. In this case, the resonator extends from the first main surface as far as the second main surface and has a main extension direction in a lateral direction.

If the first main surface and the second main surface are arranged parallel to the main extension plane, the radiation-emitting semiconductor laser is a vertical cavity surface emitting laser (for short “VCSEL”). The vertical cavity preferably corresponds to the resonator.

If the radiation-emitting semiconductor laser is the vertical cavity surface emitting laser, the resonator, in particular the vertical cavity, extends from the first main surface as far as the second main surface and has an optical axis in a vertical direction. By way of example, the first main surface, in this case arranged parallel to the main extension plane, is a radiation exit surface of the electromagnetic laser radiation.

In accordance with at least one embodiment of the radiation-emitting semiconductor laser, the first sensor layer is arranged on the first end region of the resonator. If the first main surface and the second main surface are arranged perpendicular to the main extension plane, the first end region preferably extends from the first main surface of the semiconductor body in a lateral direction to the second main surface. The first end region extends for example at most 30 micrometers in a lateral direction from the first main surface in the direction of the second main surface.

If the first main surface and the second main surface are arranged parallel to the main extension plane, the first end region generally extends from an edge of the first main surface to a midpoint of the first main surface. The first end region extends for example at most 30 micrometers in a lateral direction from the first main surface in the direction toward the midpoint of the first main surface.

The first sensor layer is preferably configured for measuring the temperature of the semiconductor body in the first end region.

A radiation-emitting semiconductor laser generally generates heat during operation. In this case, it is possible for the semiconductor laser to heat up above a critical temperature. In the event of the critical temperature being exceeded, a radiation exit surface of the semiconductor laser and/or a mirror of the semiconductor laser may be damaged. In order to counteract such damage, a maximum output power of the radiation-emitting semiconductor laser is generally limited depending on a housing temperature. The maximum output power is generally based on calculations and estimations on the basis of reliability tests, since a temperature in the region of the radiation exit surface of the radiation-emitting semiconductor laser is generally not known.

One concept behind the semiconductor laser described here is, inter alia, that a first sensor layer is arranged on the first end region of the resonator. The temperature of the semiconductor body in the region of the radiation exit surface can be measured directly by the first sensor layer. Advantageously, a maximum output power can thus be predefinable particularly accurately depending on this temperature. Advantageously, the semiconductor laser is thus operable particularly effectively.

In accordance with at least one embodiment of the radiation-emitting semiconductor laser, the first end region has a first mirror arranged on a first main surface of the semiconductor body. The first mirror is preferably a first specularly reflective coating arranged on the first main surface of the semiconductor body. Preferably, the first mirror is partly transmissive to the electromagnetic laser radiation. The first partly transmissive mirror has for example a reflectivity for the electromagnetic laser radiation of between 10% and 80% inclusive.

Preferably, the electromagnetic laser radiation is coupled out through the first partly transmissive mirror on the first main surface of the semiconductor body.

In accordance with at least one embodiment of the radiation-emitting semiconductor laser, the second end region has a second mirror arranged on a second main surface of the semiconductor body. Preferably, the second mirror is a second specularly reflective coating. The second mirror is preferably configured such that it is highly reflective for the electromagnetic laser radiation. Preferably, the second mirror reflects at least 95%, preferably at least 98% and particularly preferably at least 99% of the electromagnetic laser radiation.

Preferably, the first mirror and/or the second mirror are/is a Bragg mirror. The Bragg mirror generally comprises a multiplicity of alternately arranged dielectric layers having a different refractive index.

Alternatively, the second mirror is for example a dielectric/metal mirror. The dielectric/metal mirror comprises for example a multiplicity of dielectric layers and a multiplicity of metallic layers arranged in a manner alternating with one another.

In accordance with at least one embodiment of the radiation-emitting semiconductor laser, a second sensor layer is arranged on the second end region of the resonator. Preferably, the second sensor layer is shaped as a strip. The second sensor layer preferably has the same dimensions as the first sensor layer.

The second end region preferably extends from the second main surface of the semiconductor body in a lateral direction to the first main surface. The first end region extends for example at most 30 micrometers in a lateral direction from the second main surface in the direction of the first main surface.

The second sensor layer is preferably configured for measuring the temperature of the semiconductor body in the second end region. The second sensor layer can have the same features and embodiments as described herein for the first sensor layer.

In accordance with at least one embodiment of the radiation-emitting semiconductor laser, the semiconductor body has a ridge comprising a top surface and side surfaces adjoining the latter. Preferably, the ridge is formed by a ridge-shaped elevated region of the semiconductor body. Preferably, the ridge protrudes as a projection from a recessed outer surface of the semiconductor body. The ridge preferably extends between the first main surface and the second main surface in a lateral direction.

In accordance with at least one embodiment of the radiation-emitting semiconductor laser, the semiconductor body has the recessed outer surface arranged laterally with respect to the ridge. Preferably, the top surface of the ridge is directly connected to the recessed outer surface of the semiconductor body via the side surfaces of the ridge adjoining said top surface. The side surfaces preferably mediate a distance between the recessed outer surface laterally with respect to the ridge and the top surface in a vertical direction. Preferably, the top surface and the side surfaces and also the recessed outer surface form a step profile.

In accordance with at least one embodiment of the radiation-emitting semiconductor laser, a first electrical contact is arranged on the ridge and the recessed outer surface. The first electrical contact preferably covers the ridge at least regionally. That is to say that the first electrical contact preferably covers the top surface of the ridge, the side surfaces of the ridge and the recessed outer surface of the semiconductor body at least regionally.

The first electrical contact is preferably in electrically conductive contact with the top surface of the ridge. The first electrical contact generally serves for impressing current into the semiconductor body. The active region is preferably electrically pumped by the impressing of current. Furthermore, the first electrical contact preferably covers a large part of the semiconductor body. The first electrical contact covers for example at least 70%, in particular at least 95%, of a third main surface of the semiconductor body, for example, said third main surface being formed by the top surface and the side surfaces of the ridge and also the recessed outer surface of the semiconductor body.

A contact metal layer is preferably arranged between the top surface of the ridge and the first electrical contact. The contact metal layer is preferably configured such that it is electrically conductive and electrically conductively connected to the top surface of the ridge. Preferably, the contact metal layer is arranged exclusively on the top surface of the ridge. Furthermore, the contact metal layer preferably completely covers the top surface of the ridge. Alternatively, the top surface of the ridge in the first end region and/or the second end region is free of the contact metal layer.

The contact metal layer preferably comprises one metal or a combination of metals, such as, for example, Cu, Ti, Pt, Au, Ni, ZnO, TiWN, Rh, Pd. Alternatively or additionally, the contact metal layer comprises for example one metal oxide, such as, for example, InSnO (indium tin oxide, for short “ITO”), or a combination of metal oxides.

In accordance with at least one embodiment of the radiation-emitting semiconductor laser, the first end region is free of the first electrical contact. Preferably, the first sensor layer does not overlap the first electrical contact in a lateral direction in plan view. In particular, the first sensor layer is arranged at a distance from the first electrical contact in a lateral direction.

If the radiation-emitting semiconductor laser comprises the second sensor layer, the second end region is preferably free of the first electrical contact. Preferably, the second sensor layer does not overlap the first electrical contact in a lateral direction in plan view. In particular, the second sensor layer is arranged at a distance from the first electrical contact in a lateral direction.

In accordance with at least one embodiment of the radiation-emitting semiconductor laser, a first passivation layer is arranged between the first sensor layer and the semiconductor body. Preferably, the first passivation layer completely covers the recessed outer surface of the semiconductor body. Furthermore, the first passivation layer preferably completely covers the side surfaces of the ridge.

The first passivation layer is preferably configured such that it is electrically insulating. Furthermore, the first passivation layer preferably has a thickness in a vertical direction of at least 0.05 micrometer and at most 2 micrometers.

In accordance with at least one embodiment of the radiation-emitting semiconductor laser, the first passivation layer covers the top surface of the ridge, the side surfaces of the ridge and the recessed outer surface of the semiconductor body. Preferably, the first passivation layer completely covers the top surface of the ridge, the side surfaces of the ridge and the recessed outer surface of the semiconductor body in the first end region and/or in the second end region. Preferably, the first passivation layer is not arranged between the first electrical contact and the top surface of the ridge. That is to say that the top surface of the ridge is preferably free of the first passivation layer in a region that is covered by the first electrical contact.

In accordance with at least one embodiment of the radiation-emitting semiconductor laser, the top surface of the ridge is free of the first passivation layer. Preferably, the top surface of the ridge is completely free of the first passivation layer. That is to say that no first passivation layer is arranged between the first sensor layer and the top surface of the ridge.

In this case, the first passivation layer is preferably arranged exclusively on regions of the top surface and of the side surfaces of the ridge and on regions of the recessed outer surface of the semiconductor body which are/is not part of the first end region and/or of the second end region.

In accordance with at least one embodiment of the radiation-emitting semiconductor laser, the first sensor layer is in direct contact with the semiconductor body. Preferably, the first sensor layer is in direct contact with the top surface of the ridge. Advantageously, it is thus possible to carry out a particularly accurate temperature measurement in the first end region.

Furthermore, the second sensor layer can be in direct contact with the semiconductor body. Preferably, in this case, the second sensor layer is in direct contact with the top surface of the ridge. Advantageously, it is thus possible to carry out a particularly accurate temperature measurement in the second end region.

In accordance with at least one embodiment of the radiation-emitting semiconductor laser, a second passivation layer is arranged on the first sensor layer. Preferably, the second passivation layer does not completely cover the first sensor layer. Preferably, the second passivation layer has a length which is shorter than the length of the first sensor layer. In this case, a first edge region and a second edge region of the first sensor layer, said second edge region being situated opposite the first edge region, are free of the second passivation layer.

Moreover, a second passivation layer can be arranged on the second sensor layer. In this case, the second passivation layer preferably has a length which is shorter than the length of the second sensor layer. Preferably a first edge region and a second edge region of the second sensor layer are free of the second passivation layer.

The edge regions of the sensor layers are preferably configured for electrically contacting the sensor layers.

The first passivation layer and/or the second passivation layer are/is preferably configured as electrically insulating. The passivation layers each comprise for example an oxide, a nitride or an oxynitride or consist of one of these materials. Suitable oxides, nitrides or oxynitrides are for example silicon dioxide, silicon nitride, silicon oxynitride, aluminum oxide, tantalum oxide, rhodium oxide, niobium oxide and/or titanium dioxide. Other oxides, nitrides and oxynitrides comprising one or more of the following materials: Al, Ce, Ga, Hf, In, Mg, Nb, Rh, Sb, Si, Sn, Ta, Ti, Zn, Zr, can also be suitable as material for one of the passivation layers.

Furthermore, the second passivation layer preferably has a thickness in a vertical direction of at least 0.05 micrometer and at most 2 micrometers.

In accordance with at least one embodiment of the radiation-emitting semiconductor laser, the second passivation layer covers the top surface of the ridge and the side surfaces of the ridge.

In accordance with at least one embodiment of the radiation-emitting semiconductor laser, at least one second electrical contact is arranged on the first sensor layer. The second electrical contact is arranged for example on the first edge region of the first sensor layer. There the second electrical contact is preferably in direct electrically conductive contact with the first sensor layer.

In accordance with at least one further embodiment of the radiation-emitting semiconductor laser, at least one third electrical contact is arranged on the first sensor layer. The third electrical contact is arranged for example on the second edge region of the first sensor layer. There the third electrical contact is preferably in direct electrically conductive contact with the first sensor layer.

The first electrical contact and/or the second electrical contact and/or the third electrical contact preferably comprise(s) one metal or a combination of metals, such as, for example, Cu, Ti, Pt, Au, Ni, ZnO, TiWN, Rh, Pd.

In accordance with at least one embodiment of the radiation-emitting semiconductor laser, the second electrical contact forms a common electrical contact that is also configured for energizing the semiconductor body. The second electrical contact is preferably configured for electrically conductively contacting the first sensor layer and the semiconductor body jointly from outside.

Preferably, the third electrical contact mediates an electrically conductive connection from the second electrical contact to the first electrical contact. In this embodiment, exclusively the second electrical contact is provided for externally electrically conductively contacting the first sensor layer and the semiconductor body.

In accordance with at least one embodiment of the radiation-emitting semiconductor laser, the first sensor layer comprises a metal, a metal oxide and/or a semiconductor material.

The first sensor layer and/or the second sensor layer comprise(s) for example one metal or a combination of metals, such as, for example: Pd, Ti, Ni, Pt and/or Cu. Alternatively or additionally, the first sensor layer comprises for example one metal oxide or a combination of metal oxides, such as, for example, ZnO, InO and/or InSnO (indium tin oxide, for short “ITO”). Alternatively or additionally, the first sensor layer comprises for example one semiconductor or a combination of semiconductors, such as, for example, Si and/or Ge.

The first sensor layer can furthermore comprise a plurality of partial layers. The partial layers are preferably formed by at least one of the metals, at least one of the metal oxides and/or at least one of the semiconductors. The partial layers are formed for example by mutually different materials and/or comprise mutually different materials.

If the first sensor layer comprises a semiconductor, the first sensor layer can furthermore have dopants. Preferably, the dopant is an n-doping dopant. The dopant advantageously enables a value range of the resistance to be predefined and scaled.

Furthermore, a method for operating a radiation-emitting semiconductor laser is specified, by which method a radiation-emitting semiconductor laser described here can be operated. Therefore, all features and embodiments disclosed in association with the radiation-emitting semiconductor laser are also applicable in association with the method and vice versa.

In accordance with at least one embodiment of the method, the first sensor layer has a first resistance dependent on a temperature of the semiconductor body in the first end region.

If the radiation-emitting semiconductor laser comprises the second sensor layer, the second sensor layer preferably has a second resistance dependent on a temperature of the semiconductor body in the second end region.

In accordance with at least one embodiment of the method, the radiation-emitting semiconductor laser is operated in a manner dependent on the first resistance. Furthermore, the radiation-emitting semiconductor laser can be operated in a manner dependent on the second resistance. Preferably, the maximum output power is determined in a manner dependent on the first resistance, in particular in a manner dependent on the first resistance and the second resistance.

In this case, the maximum output power is dependent on the maximum voltage that can be applied to the radiation-emitting semiconductor laser, in the case of which the radiation-emitting semiconductor laser can be operated without being destroyed. Furthermore, the maximum output power is dependent on a reciprocal resistance of the semiconductor body that is dropped across the semiconductor body between the first semiconductor layer sequence and the second semiconductor layer sequence during operation of the radiation-emitting semiconductor laser.

If the temperature in the first end region of the semiconductor body is near the critical temperature, for example, the maximum output power of the radiation-emitting semiconductor laser is preferably reduced.

In accordance with at least one embodiment of the method, the first resistance and the semiconductor laser are connected in parallel. Preferably, the first resistance is determined by means of the second electrical contact and the third electrical contact. In this case, the first sensor layer and the semiconductor laser are arranged so as to be electrically conductively separated from one another.

If the semiconductor body heats up in the first end region, for example, the first resistance increases. This first resistance can be determined for example by an external device via the second electrical contact and the third electrical contact. The maximum output power can subsequently be determined by the external device and made available to the semiconductor body via the first electrical contact.

In accordance with at least one embodiment of the method, the first resistance and the semiconductor laser are connected in series. Preferably, the second electrically conductive contact is electrically conductively connected to the first electrically conductive contact via the third electrically conductive contact.

By way of example, the first resistance can be predefined by suitable material selection such that the maximum output power of the radiation-emitting semiconductor laser decreases in a manner dependent on the resistance.

If the semiconductor body heats up in the first end region, for example, the first resistance increases. As a result of the series connection, the maximum output power with which the semiconductor laser is operated thus decreases automatically.

The radiation-emitting semiconductor laser described here and also the method for operating the radiation-emitting semiconductor laser described here are explained in greater detail below on the basis of exemplary embodiments and with reference to the associated figures.

### BRIEF DESCRIPTION OF THE DRAWINGS

In the figures:

FIGS. 1, 2 and 3 show schematic illustrations of a radiation-emitting semiconductor laser each in accordance with one exemplary embodiment,

FIGS. 4, 5, 6, 7, 8 and 9 show a schematic sectional illustration of a radiation-emitting semiconductor laser each in accordance with one exemplary embodiment,

FIG. 10 shows a schematic illustration of a radiation-emitting semiconductor laser in accordance with one exemplary embodiment,

FIGS. 11, 12 and 13 show schematic illustrations in plan view of a radiation-emitting semiconductor laser each in accordance with one exemplary embodiment,

FIGS. 14 and 15 show schematic illustrations of an equivalent circuit diagram of a radiation-emitting semiconductor laser each in accordance with one exemplary embodiment, and

FIGS. 16 and 17 show exemplary illustrations of a resistance as a function of a temperature of a respective material of a sensor layer.

### DETAILED DESCRIPTION

Elements that are identical, of identical type or act identically are provided with the same reference signs in the figures. The figures and the size relationships of the elements illustrated in the figures along one another should not be regarded as to scale. Rather, individual elements may be illustrated with an exaggerated size in order to enable better illustration and/or in order to afford a better understanding.

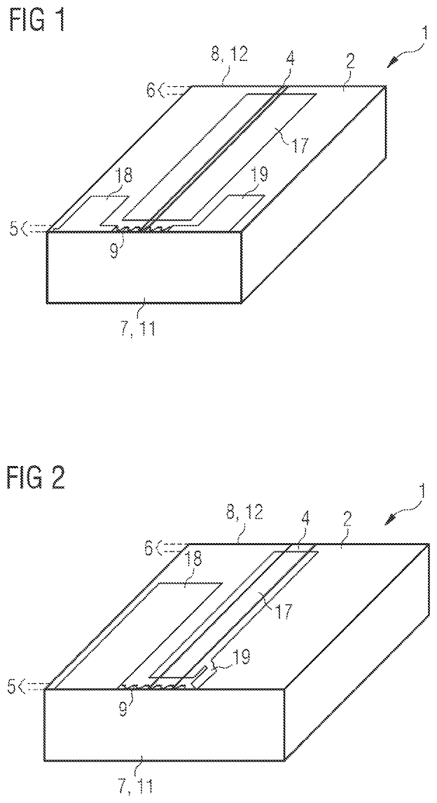

The radiation-emitting semiconductor laser 1 in accordance with the exemplary embodiment in FIG. 1 comprises a semiconductor body 2. The semiconductor body 2 is bounded by a first main surface 7 at its front side and by a second main surface 8 at its rear side. Furthermore, the semiconductor body 2 comprises an active region 3, which is described for example in association with FIG. 4. The active region 3 is arranged in a resonator 4 of the radiation-emitting semiconductor laser 1 in such a way that the electromagnetic radiation generated in the active region 3 during operation is electromagnetic laser radiation.

Furthermore, a first mirror 11 is arranged on the first main surface 7. The first mirror 11 is partly transmissive to the electromagnetic laser radiation. Moreover, a second mirror 12 is arranged on the second main surface 8. In contrast to the first mirror 11, the second mirror 12 is configured such that it is highly reflective for the electromagnetic laser radiation. In this exemplary embodiment, the electromagnetic laser radiation propagates between the first main surface 7 and the second main surface 8 along a main extension plane of the active region. The first main surface 7 is a radiation exit surface for electromagnetic laser radiation.

Moreover, a first electrical contact 17 is arranged on the semiconductor body 2. The first electrical contact 17 is in electrically conductive contact with the semiconductor body 2. In this case, the first electrical contact 17 serves for impressing current into the semiconductor body 2, the active region 3 being electrically pumped by this impressing of current.

Furthermore, a first sensor layer 9 is arranged on the semiconductor body 2 in a first end region 5 of the resonator 4, said first sensor layer being configured for measuring a temperature of the semiconductor body 2. The first sensor layer 9 is thus a temperature sensor. The first sensor layer 9 is shaped as a strip having for example a width of approximately 15 micrometers, a length of approximately 80 micrometers and a thickness in a vertical direction of approximately 800 nanometers.

A second electrical contact 18 is arranged on the first sensor layer 9 in a first edge region, said second electrical contact being in direct electrically conductive contact with the first sensor layer 9. Furthermore, a third electrical contact 19 is arranged on the first sensor layer 9 in an edge region situated opposite the first edge region, said electrical contact being in direct electrically conductive contact with the first sensor layer 9.

By way of example, a resistance of the first sensor layer 9 is able to be read out via the second electrical contact 18 and the third electrical contact 19. The temperature of the semiconductor body 2 in the first end region 5 is determinable in a manner dependent on this resistance.

In this exemplary embodiment, the first end region 5 and a second end region 6, which comprises the second main surface 8, do not overlap the first electrical contact 17 in a lateral direction in plan view. Moreover, the second electrical contact 18 and the third electrical contact 19 do not overlap the first electrical contact 17 in plan view. The second electrical contact 18 and the third electrical contact 19 here are arranged at a distance in a lateral direction and in an electrically insulating manner with respect to the first electrical contact 17.

In contrast to the exemplary embodiment in FIG. 1, in accordance with the exemplary embodiment in FIG. 2, a second electrical contact 18 is electrically conductively connected to a first electrical contact 17 via a first sensor layer 9 and a third electrical contact 19. Furthermore, the first electrical contact 17 extends as far as a second main surface 8 of the semiconductor body 2.

In this exemplary embodiment, the second electrical contact 18 forms a common electrical contact that is also configured for energizing the semiconductor body 2. Here the third electrical contact 19 mediates an electrically conductive connection from the second electrical contact 18 to the first electrical contact 17. Here exclusively the second electrical contact 18 is provided for external electrically conductive contacting.

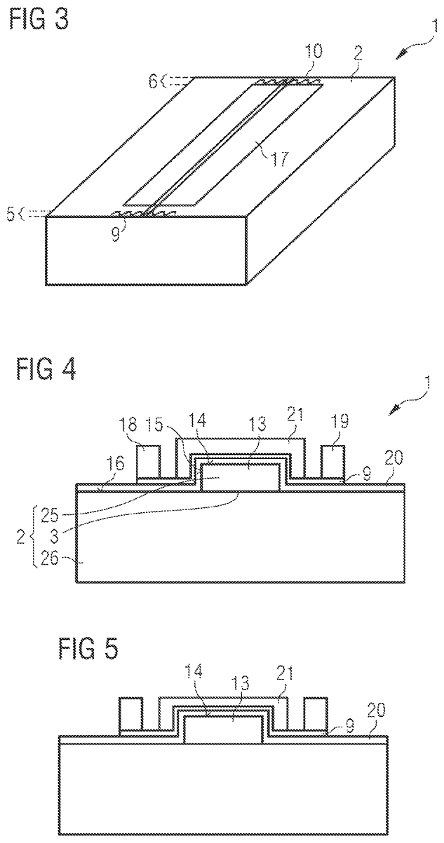

In contrast to the radiation-emitting semiconductor lasers 1 in accordance with the exemplary embodiments in FIGS. 1 and 2, the radiation-emitting semiconductor laser 1 in accordance with the exemplary embodiment in FIG. 3 comprises a second sensor layer 10. The second sensor layer 10 is arranged on a semiconductor body 2 in a second end region 6. The second sensor layer 10 is configured here for measuring a temperature of the semiconductor body 2 in the second end region 6. The second sensor layer 10 is thus likewise a temperature sensor.

The second sensor layer 10 is furthermore shaped as a strip having for example a width of approximately 15 micrometers, a length of approximately 80 micrometers and a thickness in a vertical direction of approximately 800 nanometers.

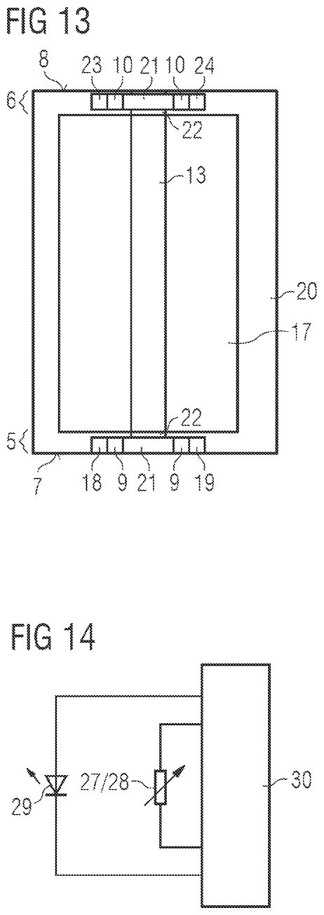

By way of example, a further second electrical contact 23 and a further third electrical contact 24 are arranged on the second sensor layer 10, as described for example in association with the exemplary embodiment in FIG. 13. By way of example, a resistance of the second sensor layer 10 is able to be read out via the further second electrical contact 23 and the further third electrical contact 24. The temperature of the semiconductor body 2 in the second end region 6 is determinable in a manner dependent on this resistance.

In accordance with the exemplary embodiment in FIG. 4, the radiation-emitting semiconductor laser 1 has a semiconductor body 2 having a ridge 13. The ridge 13 is formed by an elevated region of the semiconductor body 2. The ridge 13 has a top surface 14 and side surfaces 15 adjoining the latter. The ridge 13 extends in a lateral direction between the first main surface 7 and the second main surface 8, as described in association with the exemplary embodiments in FIGS. 1 to 3.

The semiconductor body 2 comprises a first semiconductor layer sequence 25 of a first conductivity type and a second semiconductor layer sequence 26 of a second conductivity type, which is different than the first conductivity type. The first conductivity type is for example a p-conducting type and the second conductivity type is for example an n-conducting type.

A recessed outer surface 16 of the semiconductor body 2 adjoins the side surfaces 15 of the ridge 13. Here the top surface 14 and the side surfaces 15 and also the recessed outer surface 16 form a step profile.

Between the first sensor layer 9 and the semiconductor body 2, a first passivation layer 20 is arranged in a first end region 5, described in greater detail in FIGS. 1 to 3. The first passivation layer 20 completely covers the recessed outer surface 16 of the semiconductor body 2 in the first end region 5. Furthermore, the first passivation layer 20 completely covers the top surface 14 and the side surfaces 15 of the ridge 13 in the first end region 5. The first sensor layer 9 is thus arranged completely on the first passivation layer 20.

The first passivation layer 20 is configured such that it is electrically insulating and has for example a thickness in a vertical direction of approximately 0.5 micrometer.

Furthermore, a second passivation layer 21 is arranged on the first sensor layer 9. The second passivation layer 21 here does not completely cover the first sensor layer 9. That is to say that a first edge region and a second edge region of the first sensor layer 9, said second edge region being situated opposite the first edge region, are free of the second passivation layer 21. A second electrical contact 18 is arranged on the first edge region of the first sensor layer 9, and a third electrical contact 19 is arranged on the second edge region of the first sensor layer 9. The edge regions of the first sensor layer 9 here are configured for electrically contacting the first sensor layer 9.

The second passivation layer 21 is likewise configured such that it is electrically insulating and has for example a thickness in a vertical direction of approximately 1 micrometer.

The first passivation layer 20, the first sensor layer 9 and the second passivation layer 21 are arranged one above another in each case in a positively locking manner. That is to say that the first passivation layer 20, the first sensor layer 9 and the second passivation layer 21 in each case copy the step profile of the ridge 13.

In contrast to the exemplary embodiment in FIG. 4, a top surface 14 of a ridge 13 of the semiconductor body 2 in accordance with the exemplary embodiment in FIG. 5 is free of a first passivation layer 20. In accordance with this exemplary embodiment, the top surface 14 of the ridge 13 is completely free of the first passivation layer 20. That is to say that the first sensor layer 9 is in direct contact with the top surface 14 of the ridge 13 and thus with the semiconductor body 2.

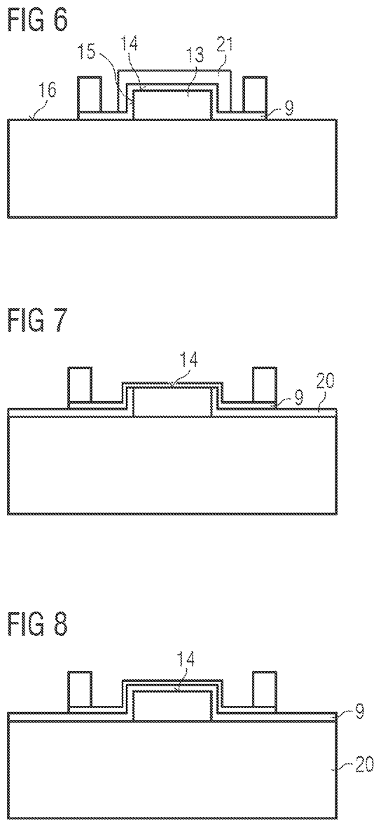

In contrast to the exemplary embodiments in FIGS. 4 to 5, the radiation-emitting semiconductor laser 1 in accordance with the exemplary embodiment in FIG. 6 does not comprise a first passivation layer 20. That is to say that the first sensor layer 9 is in direct contact with the top surface 14 and the side surfaces 15 of the ridge 13 and also with the recessed outer surface 16 of the semiconductor body 2.

In contrast to the exemplary embodiment in accordance with FIG. 5, the radiation-emitting semiconductor laser 1 in accordance with the exemplary embodiment in FIG. 7 does not comprise a second passivation layer 21. In this exemplary embodiment, the first sensor layer 9 is freely accessible from outside.

In contrast to FIG. 4, the radiation-emitting semiconductor laser 1 in accordance with the exemplary embodiment in FIG. 8 does not comprise a second passivation layer 21. In this exemplary embodiment, the first sensor layer 9 is likewise freely accessible from outside.

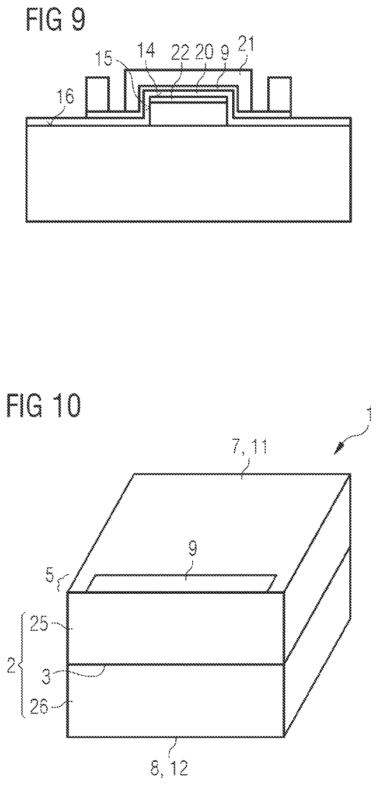

In accordance with the exemplary embodiment in FIG. 9, in contrast to FIG. 4, a contact metal layer 22 is arranged between a first passivation layer 20 and a semiconductor body 2. In this exemplary embodiment, the contact metal layer 22 completely covers a top surface 14 of a ridge 13.

In accordance with the exemplary embodiment in FIG. 10, in contrast to the exemplary embodiment in FIG. 1, a first main surface 7 and a second main surface 8 of the radiation-emitting semiconductor laser 1 run parallel to a main extension plane of the active region 3. A partly transmissive first mirror 11 is arranged on the first main surface 7 and a highly reflective second mirror 12 is arranged on the second main surface 8. In this exemplary embodiment, electromagnetic laser radiation thus propagates between the first main surface 7 and the second main surface 8 perpendicularly to the main extension plane of the active region 3.

The first main surface 7, which in this exemplary embodiment is parallel to the main extension plane of the semiconductor body 2, is a radiation exit surface for electromagnetic laser radiation. In this exemplary embodiment, the radiation-emitting semiconductor laser is a vertical cavity surface emitting laser (for short “VCSEL”).

The first sensor layer 9 is arranged on the first main surface 7 of the semiconductor body 2 in a first end region 5. By way of example, the first sensor layer 9 is in direct contact with the semiconductor body 2.

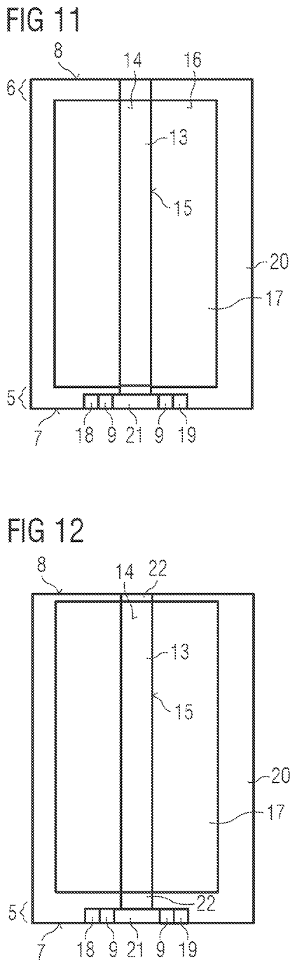

A first passivation layer 20 of the radiation-emitting semiconductor laser 1 in accordance with the exemplary embodiment in FIG. 11 is arranged over the whole area on side surfaces 15 of a ridge 13 and a recessed outer surface 16 of a semiconductor body 2, the ridge 13 being described in greater detail for example in association with FIG. 4.

Furthermore, a first electrical contact 17 is arranged on the ridge 13 and the recessed outer surface 16. The first electrical contact 17 covers the ridge 13 and the recessed outer surface 16 at least regionally. The first passivation layer 20 is arranged regionally between the first electrical contact 17 and the semiconductor body 2. In this case, the first passivation layer 20 is not arranged on the top surface 14 of the ridge 13 covered by the first electrical contact 17. That is to say that in this region the first electrical contact 17 is in electrically conductive contact with the top surface 14 of the ridge 13.

In accordance with the exemplary embodiment in FIG. 12, a contact metal layer 22 completely covers a top surface 14 of the ridge 13. Furthermore, the contact metal layer 22 is arranged exclusively on the top surface 14. Furthermore, the top surface 14 is completely free of a first passivation layer 20.

In contrast to FIG. 12, the radiation-emitting semiconductor laser 1 in accordance with the exemplary embodiment in FIG. 13 additionally comprises a second sensor layer 10 in a second end region 6.

The equivalent circuit diagram of the exemplary embodiment in FIG. 14 shows a diode 29, corresponding to a semiconductor body 2 of the radiation-emitting semiconductor laser 1, and a first resistance 27 or a second resistance 28, dropped across a first sensor layer 9 or a second sensor layer 10 during operation. The first resistance 27 or the second resistance 28 is connected in parallel with the diode 29.

The first resistance 27 is determined by means of a second electrical contact 18 and a third electrical contact 19, as described in greater detail in association with FIG. 1.

An external device 30 is configured to determine the first resistance 27. A maximum output power applied to the diode 29 for the operation of the radiation-emitting semiconductor laser 1 can subsequently be determined by the external device 29. This maximum output power is then made available to the diode 29.

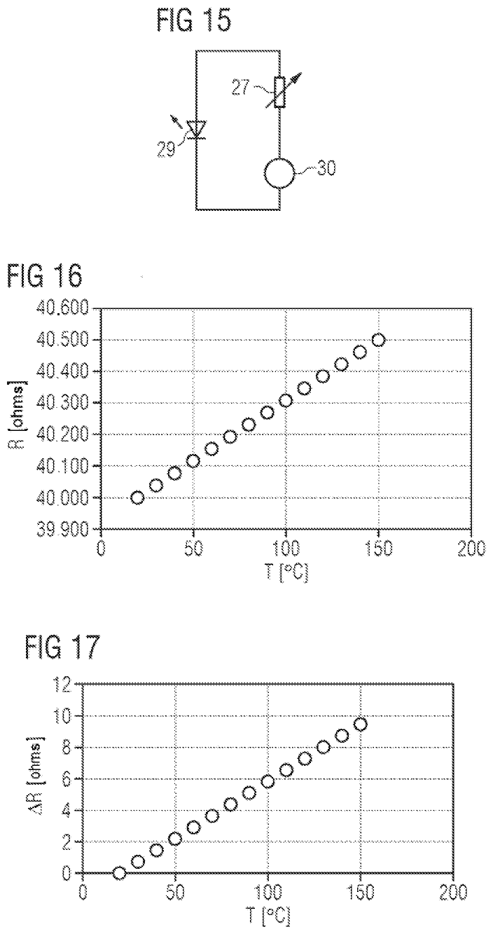

In the equivalent circuit diagram in accordance with the exemplary embodiment in FIG. 15, in contrast to the exemplary embodiment in FIG. 14, the diode 29 and the first resistance 27 are connected in series. In this exemplary embodiment, a second electrical contact 18 is electrically conductively connected to a first electrical contact 17 by means of a third electrical contact 19, as described in greater detail in association with FIG. 2. The external device 30 here is configured to provide a maximum output power.

By way of example, if the first resistance 27 increases as a result of heating, then the maximum output power with which the diode 29 is operated decreases automatically. Advantageously, the maximum output power here does not have to be adapted.

A thermal characteristic of a material of a sensor layer is plotted in accordance with the diagrams in FIGS. 16 and 17. In the diagrams in FIGS. 16 and 17, values of a resistance R of the respective material in ohms are marked in each case on the y-axis. Temperatures T in ° C. are marked on the x-axis. The resistance R of the respective material is thus plotted against the respective temperature T in each of the diagrams. In the temperature range of approximately 0° C. to approximately 150° C., the thermal characteristic of the resistance R of the materials is substantially linear. The thermal characteristic in accordance with FIG. 16 shows values of the resistance R as a function of a temperature for the metal Ti. FIG. 17 shows a thermal characteristic for the semiconductor Si. By means of n-type doping of Si, values of the resistance R in the same temperature range can be increased by approximately three orders of magnitude.

The features and exemplary embodiments described in association with the figures can be combined with one another in accordance with further exemplary embodiments, even if not all combinations are explicitly described. Furthermore, the exemplary embodiments described in association with the figures can alternatively or additionally have further features in accordance with the description in the general part.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1. A radiation-emitting semiconductor laser, comprising
a semiconductor body comprising an active region configured for generating electromagnetic radiation,
a resonator comprising a first end region and a second end region, and
a first sensor layer configured for measuring a temperature of the semiconductor body, wherein
the active region is arranged in the resonator in such a way that the electromagnetic radiation generated in the active region during operation is electromagnetic laser radiation, and
the first sensor layer is arranged on the first end region of the resonator.

2. The radiation-emitting semiconductor laser as claimed in claim 1, wherein
the first end region has a first mirror arranged on a first main surface of the semiconductor body, and
the second end region has a second mirror arranged on a second main surface of the semiconductor body.

3. The radiation-emitting semiconductor laser as claimed in claim 1, wherein a second sensor layer is arranged on the second end region of the resonator.

4. The radiation-emitting semiconductor laser as claimed in claim 1, wherein
the semiconductor body has a ridge having a top surface and side surfaces adjoining the latter,
the semiconductor body has a recessed outer surface arranged laterally with respect to the ridge, and
the first sensor layer covers the top surface, the side surfaces and the recessed outer surface.

5. The radiation-emitting semiconductor laser as claimed in the preceding claim 4, wherein
a first electrical contact is arranged on the ridge and the recessed outer surface, and
the first end region is free of the first electrical contact.

6. The radiation-emitting semiconductor laser as claimed in claim 1, wherein a first passivation layer is arranged between the first sensor layer and the semiconductor body.

7. The radiation-emitting semiconductor laser as claimed in claim 6, wherein the first passivation layer covers the top surface of the ridge, the side surfaces of the ridge and the recessed outer surface of the semiconductor body.

8. The radiation-emitting semiconductor laser as claimed in claim 6, wherein the top surface of the ridge is free of the first passivation layer.

9. The radiation-emitting semiconductor laser as claimed in claim 8, wherein the first sensor layer is in direct contact with the semiconductor body.

10. The radiation-emitting semiconductor laser as claimed in claim 1, wherein
a second passivation layer is arranged on the first sensor layer, and
the second passivation layer covers the top surface of the ridge and the side surfaces of the ridge.

11. The radiation-emitting semiconductor laser as claimed in claim 1, wherein at least one second electrical contact is arranged on the first sensor layer.

12. The radiation-emitting semiconductor laser as claimed in claim 11, wherein the second electrical contact forms a common electrical contact that is also configured for energizing the semiconductor body.

13. The radiation-emitting semiconductor laser as claimed in claim 1, wherein the first sensor layer comprises a metal, a metal oxide and/or a semiconductor material.

14. A method for operating a radiation-emitting semiconductor laser as claimed in claim 1, wherein
the first sensor layer has a first resistance dependent on a temperature of the semiconductor body in the first end region, and
the radiation-emitting semiconductor laser is operated in a manner dependent on the first resistance.

15. The method as claimed in claim 14, wherein the first resistance and the semiconductor laser are connected in parallel.

16. The method as claimed in claim 14, wherein the first resistance and the semiconductor laser are connected in series.
